(19) United States
(12) Patent Application Publication
(10) Pub. No.: US 2013/0264183 A1
(43) Pub. Date: Oct. 10, 2013

(54) CAPACITIVE TOUCH UNIT

(71) Applicant: Chih-Chung Lin, Taipei City (TW)

(72) Inventor: Chih-Chung Lin, Taipei City (TW)

(21) Appl. No.: 13/759,057

(22) Filed: Feb. 5, 2013

Related U.S. Application Data
(63) Continuation-in-part of application No. 13/442,869, filed on Apr. 10, 2012.

(51) Int. Cl. H03K 17/96

(52) U.S. Cl. CPC H03K 17/962
USPC 200/600

(57) ABSTRACT

A capacitive touch unit includes a transparent substrate, a polymeric transparent substrate, a second conductive layer and an adhesive layer. The transparent substrate is coated with at least one first conductive layer and is correspondingly attached to the polymeric transparent substrate. The second conductive layer is selectively disposed on one of two sides of the polymeric transparent substrate. The adhesive layer is disposed between the transparent substrate and the polymeric transparent substrate. By means of the capacitive touch unit, the thickness can be greatly reduced and the manufacturing cost can be greatly lowered.

This application is a Continuous-In-Part (CIP) Application of U.S. patent application Ser. No. 13/442,869, filed on Apr. 10, 2012.

### BACKGROUND OF THE INVENTION

1. Field of the Invention

The present invention relates generally to a capacitive touch unit, and more particularly to a capacitive touch unit, which can reduce the thickness and lower the manufacturing cost.

2. Description of the Related Art

In recent years, following the development of touch panel technique, various portable electronic devices with display function, such as intelligent cellular phones, tablets and MP5, have employed touch panels instead of the conventional mechanical pushbuttons that occupy much room.

In the existent touch panels, most of the touch panels adopted in the portable electronic devices are capacitive touch panels. An ordinary capacitive touch panel includes a transparent substrate. An indium tin oxide (ITO) layer is disposed on a bottom face of the transparent substrate. The periphery of the bottom face serves as a wiring section. Multiple electrodes are formed on the indium tin oxide (ITO) layer. Multiple leads are disposed on the wiring section and electrically connected to the electrodes respectively. The leads are non-transparent bodies. Therefore, it is necessary for the electronic device manufacturer to spray an ink layer on the periphery of a bottom section of a protection board and dispose an adhesive layer on a top face of the touch panel for adhering the touch panel to the protection board. The ink layer of the bottom face of the protection board corresponds to the wiring section of the touch panel for concealing the leads arranged in the wiring section of the touch panel. The ink layer and the adhesive layer not only lead to increase of manufacturing cost and material cost of the electronic device, but also lead to increase of the total thickness of the electronic device. As a result, the portable electronic device can be hardly slimmed, miniaturized and lightened. This problem must be solved.

Some manufacturers manufacture the touch panels by means of lithography. Such technique can meet the requirement for thinning the touch panel. However, the manufacturing cost is greatly increased. Therefore, the conventional touch panel has the following shortcomings:

1. The conventional touch panel has larger thickness.

2. The manufacturing cost of the conventional touch panel is higher.

### SUMMARY OF THE INVENTION

A primary object of the present invention is to provide a capacitive touch unit, which can reduce the total thickness of the capacitive touch panel.

A further object of the present invention is to provide the above capacitive touch unit, which can greatly lower the manufacturing cost.

To achieve the above and other objects, the capacitive touch unit of the present invention includes a transparent substrate, a polymeric transparent substrate, a second conductive layer and an adhesive layer.

The transparent substrate has a first side and a second side. The second side is coated with at least one first conductive layer. The polymeric transparent substrate has a third side and a fourth side. The third side is correspondingly attached to the first conductive layer. The second conductive layer is selectively disposed on the third side or the fourth side of the polymeric transparent substrate. The adhesive layer is disposed between the transparent substrate and the polymeric transparent substrate.

By means of the capacitive touch unit of the present invention, the total thickness of the capacitive touch panel can be greatly reduced and the manufacturing cost of the capacitive touch panel can be greatly lowered.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein:

FIG. 1 is a perspective view of a first embodiment of the capacitive touch unit of the present invention;

FIG. 2 is a sectional view of the first embodiment of the capacitive touch unit of the present invention;

FIG. 3 is a sectional view of a second embodiment of the capacitive touch unit of the present invention;

FIG. 4 is a sectional view of a third embodiment of the capacitive touch unit of the present invention;

FIG. 5 is a sectional view of a fourth embodiment of the capacitive touch unit of the present invention;

FIG. 6 is a sectional view of a fifth embodiment of the capacitive touch unit of the present invention; and

FIG. 7 is a sectional view of a sixth embodiment of the capacitive touch unit of the present invention.

### DETAILED DESCRIPTION OF THE PREFERRED EMBODIMENTS

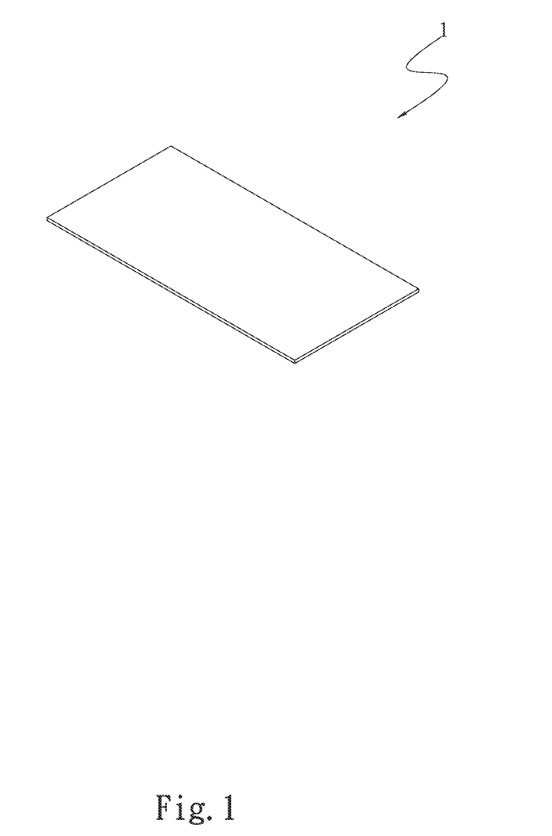

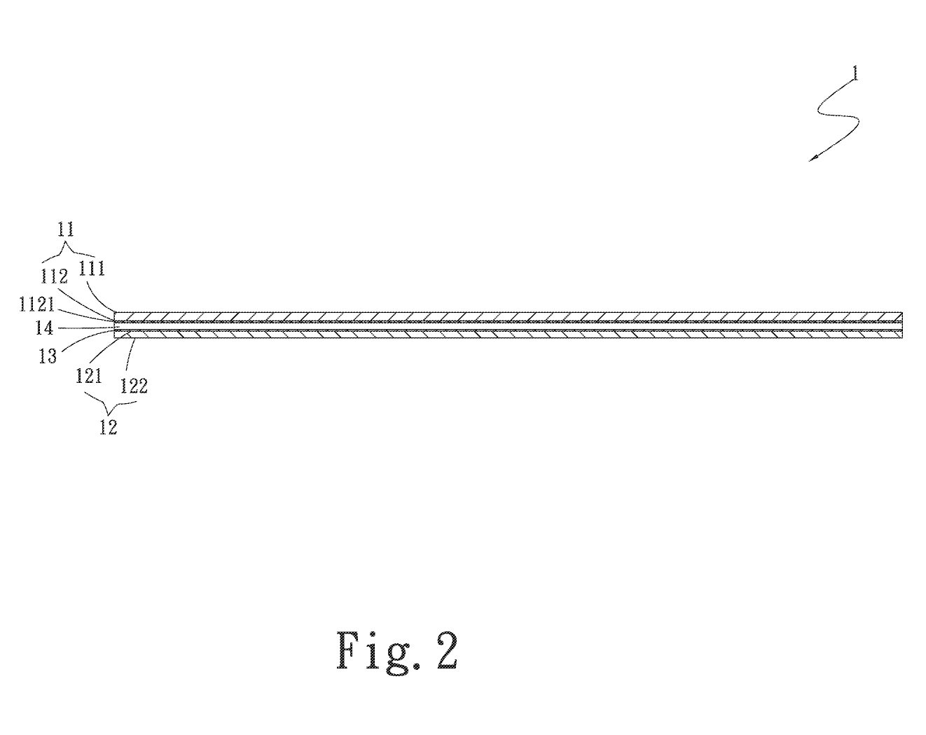

Please refer to FIGS. 1 and 2. FIG. 1 is a perspective view of a first embodiment of the capacitive touch unit of the present invention. FIG. 2 is a sectional view of the first embodiment of the capacitive touch unit of the present invention. According to the first embodiment, the capacitive touch unit 1 of the present invention includes a transparent substrate 11, a polymeric transparent substrate 12, a second conductive layer 13 and an adhesive layer 14.

The transparent substrate 11 has a first side 111 and a second side 112. The second side 112 is coated with at least one first conductive layer 1121.

The polymeric transparent substrate 12 has a third side 121 and a fourth side 122. The third side 121 is correspondingly attached to the first conductive layer 1121.

The second conductive layer 13 is selectively disposed on the third side 121 or the fourth side 122 of the polymeric transparent substrate 12. In this embodiment, the second conductive layer 13 is disposed on the third side 121 of the polymeric transparent substrate 12.

The adhesive layer 14 is disposed between the transparent substrate 11 and the polymeric transparent substrate 12.

The transparent substrate 11 is selected from a group consisting of a glass substrate and a polymeric transparent substrate. In this embodiment, the transparent substrate 11 is, but not limited to, a glass substrate for illustration purposes only.

The material of the polymeric transparent substrate 12 is selected from a group consisting of polyethylene terephthalate (PET), polycarbonate (PC), polyethylene (PE), polyvinyl chloride (PVC), polypropylene (PP), polystyrene (PS), polymethylmethacrylate (PMMA), and cycloolefin copolymer (COC). In this embodiment, the polymeric transparent substrate 12 is, but not limited to, a polyethylene terephthalate (PET) substrate for illustration purposes only.

The adhesive layer 14 is selected from a group consisting of optical clear adhesive (OCA) and optical clear resin (OCR).

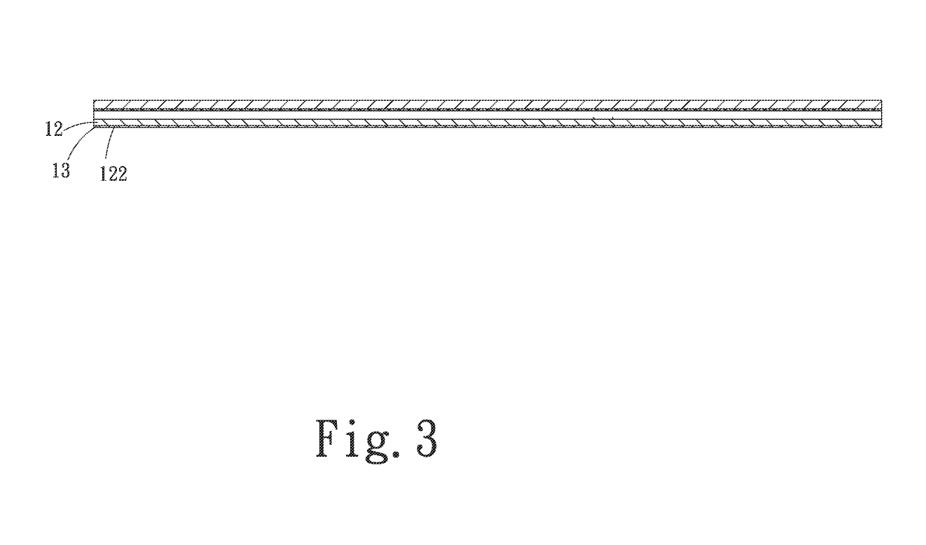

Please now refer to FIG. 3, which is a sectional view of a second embodiment of the capacitive touch unit of the present invention. The second embodiment is partially identical to the first embodiment in structure and thus will not be repeatedly described hereinafter. The second embodiment is different from the first embodiment in that the second conductive layer 13 is disposed on the fourth side 122 of the polymeric transparent substrate 12.

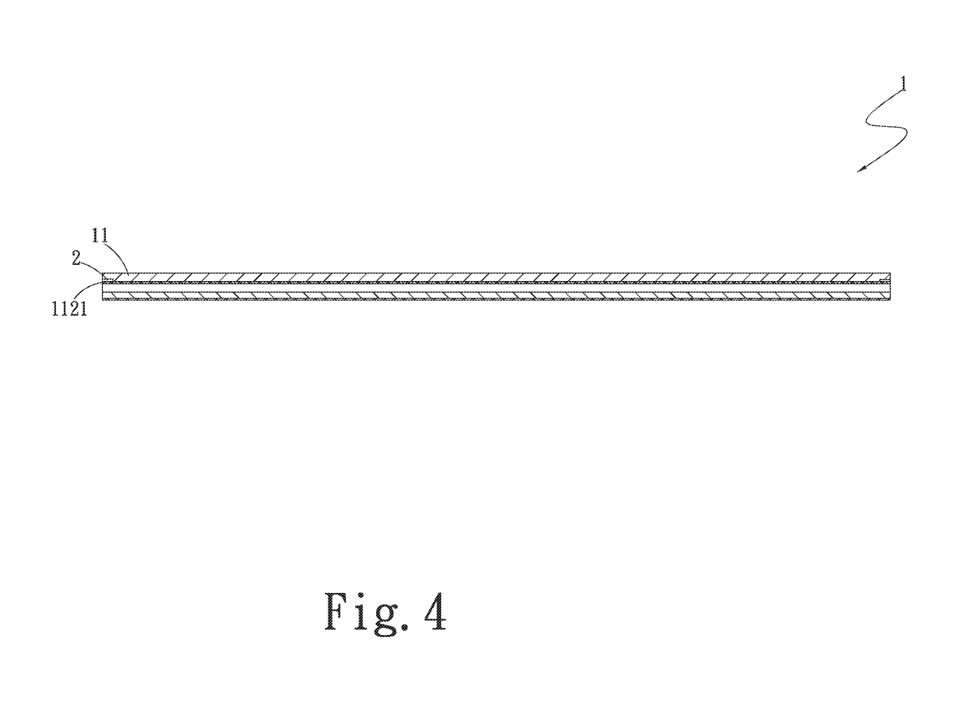

Please now refer to FIG. 4, which is a sectional view of a third embodiment of the capacitive touch unit of the present invention. The third embodiment is partially identical to the first embodiment in structure and thus will not be repeatedly described hereinafter. The third embodiment is different from the first embodiment in that the capacitive touch unit 1 further includes a shield body 2. The shield body 2 is disposed between the transparent substrate 11 and the first conductive layer 1121 in adjacency to a lateral side of the transparent substrate 11.

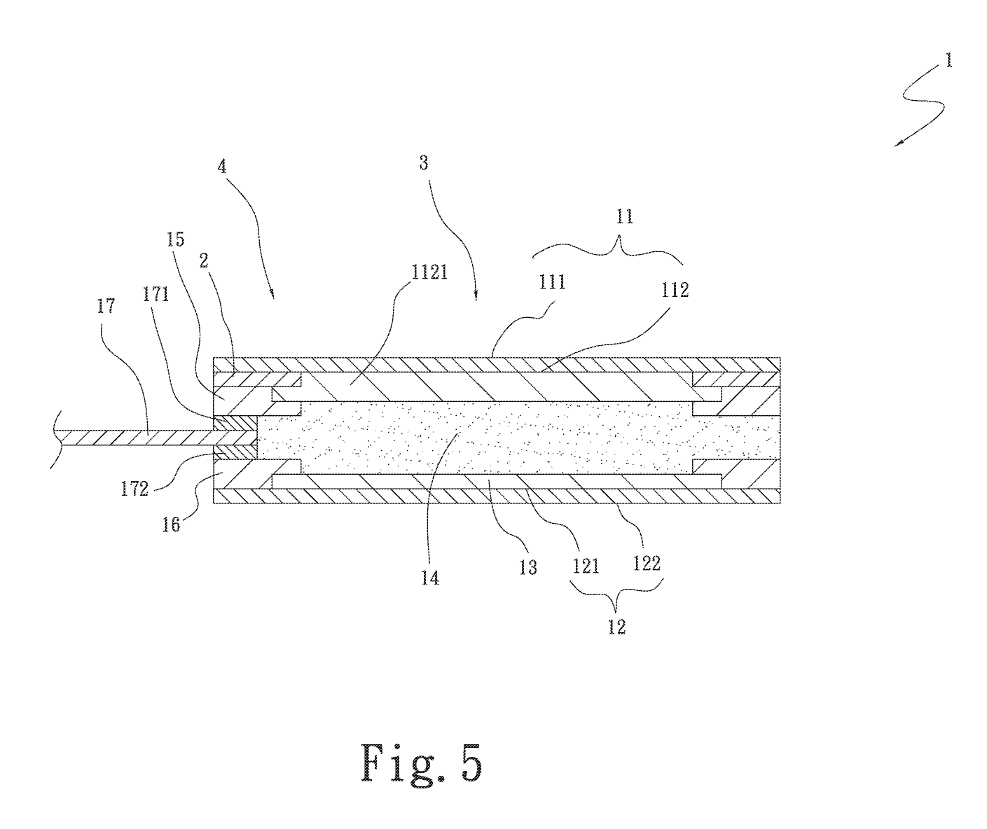

Please now refer to FIG. 5, which is a sectional view of a fourth embodiment of the capacitive touch unit of the present invention. The fourth embodiment is partially identical to the first embodiment in structure and thus will not be repeatedly described hereinafter. The fourth embodiment is different from the first embodiment in that the capacitive touch unit 1 includes a transparent substrate 11, a polymeric transparent substrate 12, a touch section 3, a non-touch section 4, a shield body 2, a first conductive layer 1121, a second conductive layer 13, an adhesive layer 14, a first lead layer 15, a second lead layer 16 and a flexible circuit board 17.

The transparent substrate 11 has a first side 111 and a second side 112. The polymeric transparent substrate 12 has a third side 121 and a fourth side 122. The transparent substrate 11 corresponds to the polymeric transparent substrate 12. The touch section 3 is disposed at the center of the transparent substrate 11 and the center of the polymer transparent substrate 12. The non-contact section 4 is disposed around the touch section 3.

The shield body 2 is disposed on the second side 112 in the non-contact section 4. The first lead layer 15 is disposed on one side of the shield body 2, which side is distal from the second side 112. The second lead layer 16 is disposed on the third side 121 of the polymer transparent substrate 12 in adjacency to the second conductive layer 13. The flexible circuit board 17 is disposed in the non-contact section 4. A first conductive adhesive layer 171 and a second conductive adhesive layer 172 are respectively disposed on two sides of the flexible circuit board 17. The flexible circuit board 17 are respectively electrically connected to the first and second lead layers 15, 16 via the first and second conductive adhesive layers 171, 172. The adhesive layer 14 is disposed between the transparent substrate 11 and the polymer transparent substrate 12.

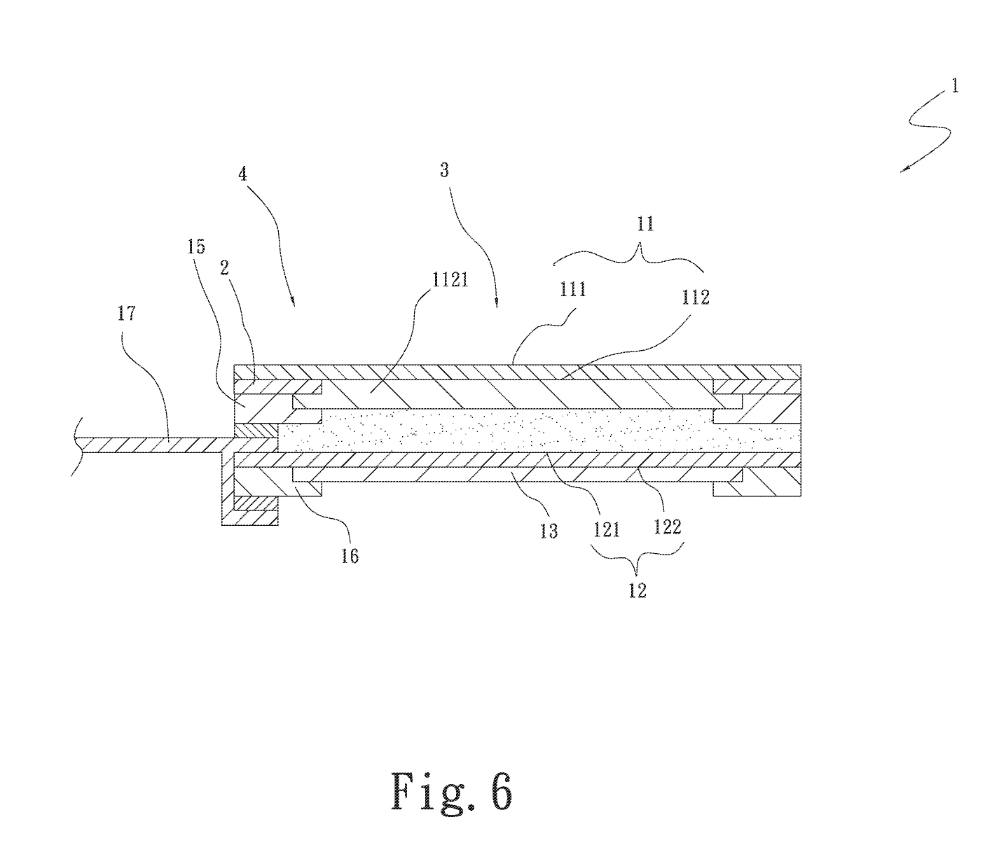

Please now refer to FIG. 6, which is a sectional view of a fifth embodiment of the capacitive touch unit of the present invention. The fifth embodiment is partially identical to the fourth embodiment in structure and thus will not be repeatedly described hereinafter. The fifth embodiment is different from the fourth embodiment in that the fifth embodiment of the capacitive touch unit 1 includes a transparent substrate 11, a polymeric transparent substrate 12, a touch section 3, a non-touch section 4, a shield body 2, a first conductive layer 1121, a second conductive layer 13, an adhesive layer 14, a first lead layer 15, a second lead layer 16 and a flexible circuit board 17. The second conductive layer 13 is disposed on the fourth side 122 of the polymer transparent substrate 12 in the touch section 3 and partially extends to the non-contact section 4. The second lead layer 16 is disposed on the fourth side 122 of the polymer transparent substrate 12 in adjacency to the second conductive layer 13.

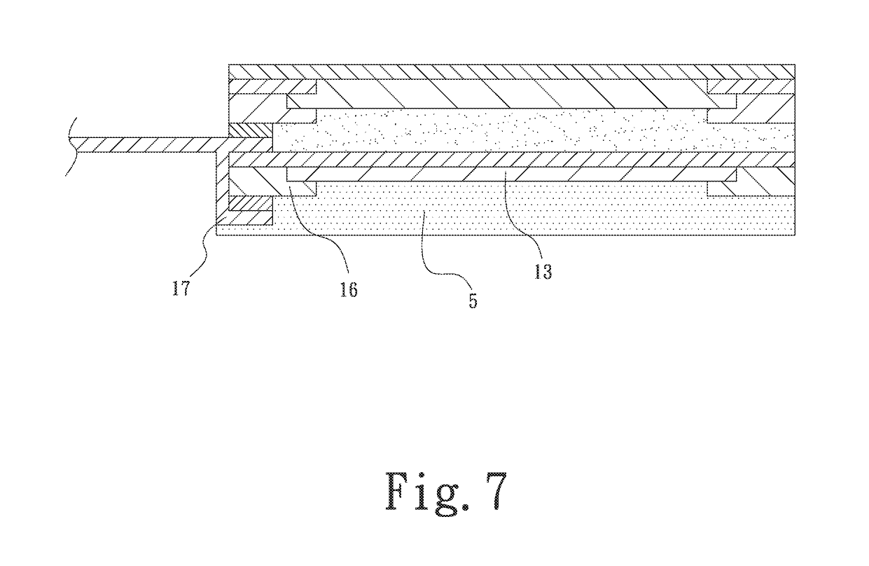

Please now refer to FIG. 7, which is a sectional view of a sixth embodiment of the capacitive touch unit of the present invention. The sixth embodiment is partially identical to the fifth embodiment in structure and thus will not be repeatedly described hereinafter. The sixth embodiment is different from the fifth embodiment in that the sixth embodiment further includes a protection layer 5. The protective layer 5 covers one end of the flexible circuit board 17, one side of the second conductive layer 13 and one side of the second lead layer 16.

In the first and sixth embodiments, the first and second conductive layers 1121, 13 are transparent conductive layers. The transparent conductive layers are coating structures formed by means of gelatinization, plating, evaporation or sputtering. The coating structure is selected from a group consisting of indium tin oxide (ITO), indium zinc oxide (IZO) and antimony tin oxide (ATO).

By means of the structural design of the capacitive touch unit 1 of the present invention, the problem existing in the conventional touch panel that the conventional touch panel cannot be thinned can be solved. Moreover, the manufacturing cost can be greatly lowered.

The above embodiments are only used to illustrate the present invention, not intended to limit the scope thereof. It is understood that many changes and modifications of the above embodiments can be made without departing from the spirit of the present invention. The scope of the present invention is limited only by the appended claims.

What is claimed is:

1. A capacitive touch unit comprising:
a transparent substrate having a first side and a second side, the second side being coated with at least one first conductive layer;
a polymeric transparent substrate having a third side and a fourth side, the third side being correspondingly attached to the first conductive layer;
a second conductive layer selectively disposed on the third side or the fourth side of the polymeric transparent substrate; and
an adhesive layer disposed between the transparent substrate and the polymeric transparent substrate.

2. The capacitive touch unit as claimed in claim 1, wherein the transparent substrate is selected from a group consisting of a glass substrate and a polymeric transparent substrate.

3. The capacitive touch unit as claimed in claim 1, wherein the material of the polymeric transparent substrate is selected from a group consisting of polyethylene terephthalate (PET), polycarbonate (PC), polyethylene (PE), polyvinyl chloride (PVC), polypropylene (PP), polystyrene (PS), polymethylmethacrylate (PMMA), and cycloolefin copolymer (COC).

4. The capacitive touch unit as claimed in claim 1, wherein the adhesive layer is selected from a group consisting of optical clear adhesive (OCA) and optical clear resin (OCR).

5. The capacitive touch unit as claimed in claim 1, further comprising a shield body, the shield body being disposed between the transparent substrate and the first conductive layer in adjacency to a lateral side of the transparent substrate.

6. The capacitive touch unit as claimed in claim 1, wherein the first and second conductive layers are transparent conductive layers, the transparent conductive layers being coating structures formed by means of gelatinization, plating, evaporation or sputtering, the coating structure being selected from a group consisting of indium tin oxide (ITO), indium zinc oxide (IZO) and antimony tin oxide (ATO).

7. A capacitive touch unit comprising:
a transparent substrate having a first side and a second side;
a polymeric transparent substrate having a third side and a fourth side;
a touch section disposed at a center of the transparent substrate and a center of the polymer transparent substrate;
a non-contact section disposed around the touch section;
a shield body disposed on the second side in the non-contact section;
a first conductive layer coated on the second side in the contact section and partially extending to the non-contact section;
a second conductive layer disposed on the third side of the polymer transparent substrate in the touch section and partially extending to the non-contact section;
a first lead layer disposed on one side of the shield body, which side is distal from the second side;
a second lead layer disposed on the third side of the polymer transparent substrate in adjacency to the second conductive layer;
a flexible circuit board disposed in the non-contact section, a first conductive adhesive layer and a second conductive adhesive layer being respectively disposed on two sides of the flexible circuit board, the flexible circuit board being respectively electrically connected to the first and second lead layers via the first and second conductive adhesive layers; and
an adhesive layer disposed between the transparent substrate and the polymer transparent substrate.

8. The capacitive touch unit as claimed in claim 7, wherein the transparent substrate is selected from a group consisting of a glass substrate and a polymeric transparent substrate.

9. The capacitive touch unit as claimed in claim 7, wherein the material of the polymeric transparent substrate is selected from a group consisting of polyethylene terephthalate (PET), polycarbonate (PC), polyethylene (PE), polyvinyl chloride (PVC), polypropylene (PP), polystyrene (PS), polymethylmethacrylate (PMMA), and cycloolefin copolymer (COC).

10. The capacitive touch unit as claimed in claim 7, wherein the adhesive layer is selected from a group consisting of optical clear adhesive (OCA) and optical clear resin (OCR).

11. The capacitive touch unit as claimed in claim 7, wherein the first and second conductive layers are transparent conductive layers, the transparent conductive layers being coating structures formed by means of gelatinization, plating, evaporation or sputtering, the coating structure being selected from a group consisting of indium tin oxide (ITO), indium zinc oxide (IZO) and antimony tin oxide (ATO).

12. A capacitive touch unit comprising:
a transparent substrate having a first side and a second side;
a polymeric transparent substrate having a third side and a fourth side;
a touch section disposed at a center of the transparent substrate and a center of the polymer transparent substrate;
a non-contact section disposed around the touch section;
a shield body disposed on the second side in the non-contact section;
a first conductive layer coated on the second side in the contact section and partially extending to the non-contact section;
a second conductive layer disposed on the fourth side of the polymer transparent substrate in the touch section and partially extending to the non-contact section;
a first lead layer disposed on one side of the shield body, which side is distal from the second side;
a second lead layer disposed on the fourth side of the polymer transparent substrate in adjacency to the second conductive layer;
a flexible circuit board disposed in the non-contact section, a first conductive adhesive layer and a second conductive adhesive layer being respectively disposed on two sides of the flexible circuit board, the flexible circuit board being respectively electrically connected to the first and second lead layers via the first and second conductive adhesive layers; and
an adhesive layer disposed between the transparent substrate and the polymer transparent substrate.

13. The capacitive touch unit as claimed in claim 12, wherein the transparent substrate is selected from a group consisting of a glass substrate and a polymeric transparent substrate.

14. The capacitive touch unit as claimed in claim 12, wherein the material of the polymeric transparent substrate is selected from a group consisting of polyethylene terephthalate (PET), polycarbonate (PC), polyethylene (PE), polyvinyl chloride (PVC), polypropylene (PP), polystyrene (PS), polymethylmethacrylate (PMMA), and cycloolefin copolymer (COC).

15. The capacitive touch unit as claimed in claim 12, wherein the adhesive layer is selected from a group consisting of optical clear adhesive (OCA) and optical clear resin (OCR).

16. The capacitive touch unit as claimed in claim 12, wherein the first and second conductive layers are transparent conductive layers, the transparent conductive layers being coating structures formed by means of gelatinization, plating, evaporation or sputtering, the coating structure being selected from a group consisting of indium tin oxide (ITO), indium zinc oxide (IZO) and antimony tin oxide (ATO).

17. The capacitive touch unit as claimed in claim 12, further comprising a protection layer, the protective layer covering one end of the flexible circuit board, one side of the second conductive layer and one side of the second lead layer.
